(19) United States
(12) Patent Application Publication
(10) Pub. No.: US 2015/0170997 A1
(43) Pub. Date: Jun. 18, 2015

(54) MEMS DEVICE AND MANUFACTURING METHOD OF THE SAME

(71) Applicant: KABUSHIKI KAISHA TOSHIBA, Tokyo (JP)

(72) Inventor: Naofumi NAKAMURA, Tokyo (JP)

(73) Assignee: KABUSHIKI KAISHA TOSHIBA, Tokyo (JP)

(21) Appl. No.: 14/476,452

(22) Filed: Sep. 3, 2014

(30) Foreign Application Priority Data
Dec. 13, 2013 (JP) 2013-258308

(51) Int. Cl. H01L 23/48; B81B 3/00; B81C 1/00; H01L 21/768

(52) U.S. Cl. CPC H01L 23/481; H01L 21/768; B81B 3/0018; B81C 1/00015

(57) ABSTRACT

According to one embodiment, a MEMS device is disclosed. The device includes a substrate, a MEMS element provided on the substrate, a first film having a plurality of first through holes. The first film and the substrate form a cavity containing the MEMS element. The device further includes a second film provided on the first film, and including a second through hole communicating with a first through hole of the plurality of first through holes, and a third film provided on the second film, and closing the first through hole communicating with the second through hole.

### CROSS-REFERENCE TO RELATED APPLICATIONS

This application is based upon and claims the benefit of priority from Japanese Patent Application No. 2013-258308, filed Dec. 13, 2013, the entire contents of which are incorporated herein by reference.

### FIELD

Embodiments described herein relate generally to a MEMS device including a MEMS (Micro Electro Mechanical Systems) element and a manufacturing method of the same.

### BACKGROUND

A MEMS device comprises a substrate, a fixed electrode (lower electrode), a movable electrode (upper electrode) and a diaphragm. The substrate and the diaphragm form a cavity which contains the fixed electrode and the movable electrode. The diaphragm includes a cap film having through holes and a cap film which is formed on the above cap film to close the through holes.

### BRIEF DESCRIPTION OF THE DRAWINGS

FIG. 1 is a cross-sectional view for explaining for a manufacturing method of a MEMS device according to first embodiment.

FIG. 2 is a cross-sectional view for explaining for the manufacturing method of the MEMS device according to the first embodiment, subsequently to FIG. 1.

FIG. 3 is a cross-sectional view for explaining for the manufacturing method of the MEMS device according to the first embodiment, subsequently to FIG. 2.

FIG. 4 is a cross-sectional view for explaining for the manufacturing method of the MEMS device according to the first embodiment, subsequently to FIG. 3.

FIG. 5 is a cross-sectional view for explaining for the manufacturing method of the MEMS device according to the first embodiment, subsequently to FIG. 4.

FIG. 6 is a cross-sectional view for explaining for the manufacturing method of the MEMS device according to the first embodiment, subsequently to FIG. 5.

FIG. 7 is a cross-sectional view for explaining for the manufacturing method of the MEMS device according to the first embodiment, subsequently to FIG. 6.

FIG. 8 is a cross-sectional view for explaining for the manufacturing method of the MEMS device according to the first embodiment, subsequently to FIG. 7.

FIG. 9 is a cross-sectional view for explaining for the manufacturing method of the MEMS device according to the first embodiment, subsequently to FIG. 8.

FIG. 10 is a cross-sectional view for explaining for the manufacturing method of the MEMS device according to the first embodiment, subsequently to FIG. 9.

FIG. 11 is a cross-sectional view for explaining for the manufacturing method of the MEMS device according to the first embodiment, subsequently to FIG. 10.

FIG. 12 is a cross-sectional view for explaining for an alternative manufacturing method of the MEMS device according to the first embodiment.

FIG. 13 is a cross-sectional view for explaining for the alternative manufacturing method of the MEMS device according to the first embodiment, subsequently to FIG. 12.

FIG. 14 is a cross-sectional view for explaining for the alternative manufacturing method of the MEMS device according to the first embodiment, subsequently to FIG. 13.

FIG. 15 is a cross-sectional view for explaining for a manufacturing method of a MEMS device according to second embodiment.

FIG. 16 is a cross-sectional view for explaining for the manufacturing method of the MEMS device according to the second embodiment, subsequently to FIG. 15.

FIG. 17 is a cross-sectional view for explaining for the manufacturing method of the MEMS device according to the second embodiment, subsequently to FIG. 16.

FIG. 18 is a cross-sectional view for explaining for the manufacturing method of the MEMS device according to the second embodiment, subsequently to FIG. 17.

FIG. 19 is a cross-sectional view for explaining for the manufacturing method of the MEMS device according to the second embodiment, subsequently to FIG. 18.

FIG. 20 is a cross-sectional view for explaining for an alternative manufacturing method of the MEMS device according to the second embodiment.

FIG. 21 is a cross-sectional view for explaining for the alternative manufacturing method of the MEMS device according to the second embodiment, subsequently to FIG. 20.

FIG. 22 is a cross-sectional view for explaining for the alternative manufacturing method of the MEMS device according to the second embodiment, subsequently to FIG. 21.

### DETAILED DESCRIPTION

Embodiments will be described hereinafter with reference to the accompanying drawings. In the drawings, the same reference numbers denote the same reference numbers or corresponding portions, and duplicated descriptions are made as needed.

In general, according to one of the embodiments, there is provided a MEMS device. The device includes a substrate, a MEMS element provided on the substrate, a first film having a plurality of first through holes. The first film and the substrate form a cavity containing the MEMS element. The device further includes a second film provided on the first film, and Including a second through hole communicating with a first through hole of the plurality of first through holes, and a third film provided on the second film, and closing the first through hole communicating with the second through hole.

According to another embodiment, there is provided a manufacturing method of a MEMS device. The method includes forming a MEMS element on a substrate, forming a sacrifice layer covering the MEMS element on the substrate, forming a first film including a plurality of first through holes on the sacrifice layer;

removing the sacrifice layer via the plurality of first through holes to form a cavity which contains the MEMS element, and includes the substrate and the first film. The method further includes forming a second film on the first film to close the plurality of first through holes, forming a second through hole in the second film, wherein the second through hole communicates with a first through hole of the plurality of first through holes; and, forming a third film on the second film to close the first through hole communicating with the second through hole.

### First Embodiment

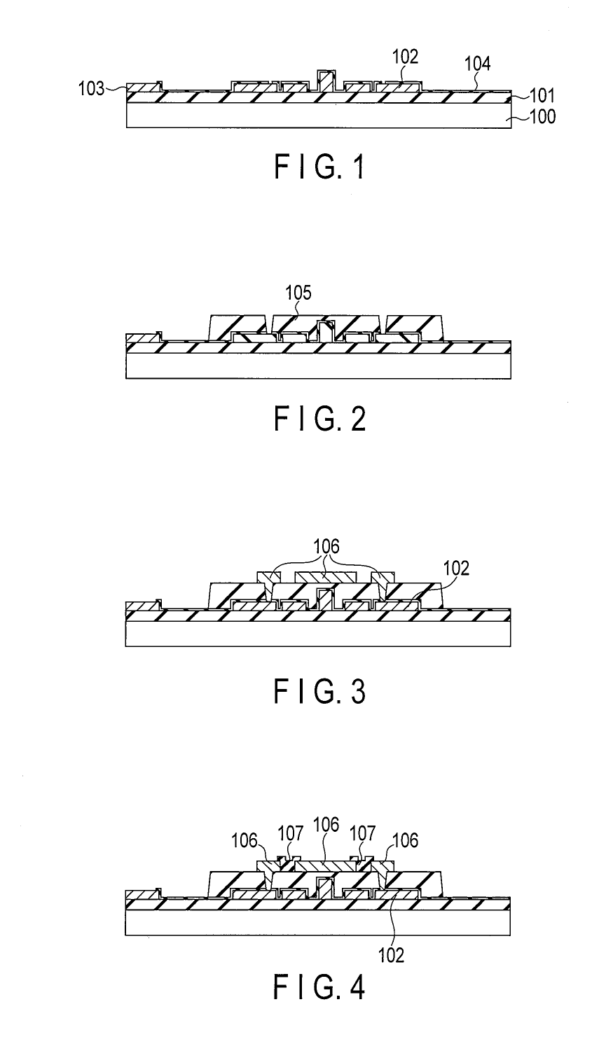

FIG. 1 to FIG. 11 are cross-sectional views for explaining a manufacturing method of a MEMS device according to first embodiment.

[FIG. 1]

An insulation film 101 is formed on a substrate 100. The substrate 100 is, for example, a silicon substrate (semiconductor substrate). The insulation film 101 is, for example, a silicon oxide film. A substrate such as an SOI substrate may be used instead of the substrate 100.

Next, a conductive film to be processed into a first interconnect (fixed electrode) 102 and a pad 103 is formed on the insulation film 101. The first interconnect 102 and the pad 103 are formed by processing the above conductive film by using photolithography method and etching method. The etching is, for example, RIE (Reactive Ion Etching) method. Wet etching may be employed instead of RIE method. This conductive film is, for example, an aluminum film. This aluminum film is formed by, for example, sputtering method. A thickness of the first interconnect is, for example, a few hundred nm to a few μm.

Next, a passivation film 104 is formed on a region including the insulation film 101, the first interconnect 102 and the pad 103. Then, a connection hole for the first interconnect 102 and the pad 103 is opened in the passivation film 104 by photolithography method and RIE method. The passivation film 104 is formed by, for example, CVD (Chemical Vapor Deposition). The passivation film 104 is, for example, an insulation film such as a silicon oxide film and a silicon nitride film. A thickness of the passivation film 104 is, for example, a few nm to a few μm.

[FIG. 2]

A first sacrifice layer 105 having a predetermined shape is formed on the first interconnect 102 and the passivation film 104. The first sacrifice layer 105 has a through hole which communicates with the connection hole of the first interconnect 102. The sacrifice layer 105 is, for example, an insulating film employing organic substance such as polyimide as a material. The thickness of the first sacrifice layer 105 is, for example, a few hundred nm to a few μm.

The first sacrifice layer 105 can be formed, for example, according to the following three manners.

According to the first manner, an insulating film (coating film) with a few hundred nm to a few μm thickness, which is to be processed into the first sacrifice layer 105, is formed on the entire surface by coating method, thereafter, unnecessary portion of the above coating film is removed by lithography and development, and thereby the first sacrifice layer 105 having the predetermined shape is formed.

According to the second manner, after the coating film is formed, a resist pattern is formed on the coating film by using lithography method, then the coating film is etched by RIE method using the resist pattern as a mask, and thereby the first sacrifice layer 105 having the predetermined is formed.

According to the third manner, the coating film is formed, thereafter, a hard mask is formed on the coating film, then the coating film is etched by RIE method or wet process using the hard mask as a mask, and thereby the first sacrifice layer 105 having the predetermined is formed. The step of forming the hard mask includes a step of forming an insulating film such as a silicon oxide film or silicon nitride film on the coating film, a step of forming a resist pattern on the insulating film, and a step of etching the insulating by RIE method using the resist pattern as a mask.

[FIG. 3]

A conductive film such as an aluminum film is formed on an entire surface to fill the through holes of the first sacrifice layer 105, thereafter, a plurality of second interconnects (movable electrodes) 106 are formed by processing the conductive film. The processing of the conductive film is executed by, for example, photolithography method and RIE method. Wet etching method may be employed instead of RIE method. The thickness of the second interconnects 106 are, for example, a few hundred nm to a few μm. Two outer interconnects of the second interconnects 106 are connected to the first interconnect 102 via the through holes of the first sacrifice layer 105.

[FIG. 4]

A insulating film such as silicon nitride film with a few hundred nm to a few μm thickness is deposited by CVD method, thereafter, an insulating connection portion 107 connecting the second interconnects 106 with each other is formed by processing the insulating film by using photolithography method and etching method. MEMS element (102, 106, 107) is thus completed. Here, the insulating connection portion is exemplified, but a connection portion formed of metal, i.e., a conductive connection portion may be used.

[FIG. 5]

Following that, a WLP (Wafer Level Package) process proceeds.

A second sacrifice layer 108 having a predetermined shape which covers a region including the fixed electrode 102, the movable electrode 106 and connection portion 107 of the MEMS element, is formed. The second sacrifice layer 108 has a flat top face. The second sacrifice layer 108 is obtained by, for example, forming a film (coating film) with a few hundred nm to a few μm thickness employing an organic substance such as polyimide as a material by coating method, and then by patterning the coating film.

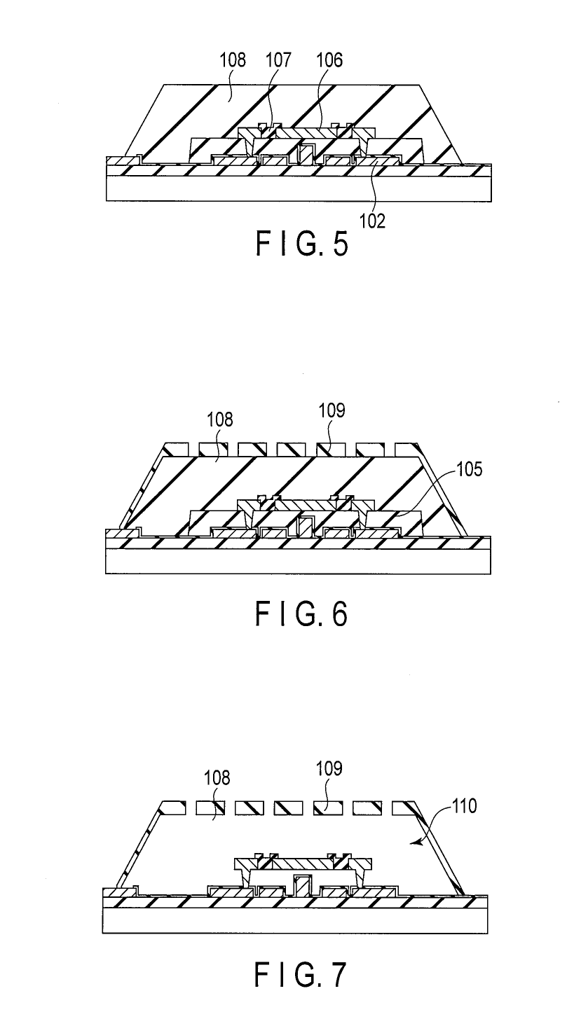

Relating to the patterning method of the coating film, a method that includes removing unnecessary portions of the second sacrifice layer 108 by exposure and development after the coating of the second sacrifice layer 108, or a method that includes forming a resist pattern on the second sacrifice layer 108 by using lithography method, and removing unnecessary portions of the second sacrifice layer 108 by etching the second sacrifice layer 108 using RIE method with the resist pattern as a mask, or a method that includes forming a hard mask on the second sacrifice layer 108, and removing unnecessary portions of the second sacrifice layer 108 by etching the second sacrifice layer 108 using RIE method or wet process with the hard mask as a mask, may be provided.

[FIG. 6]

A first cap film 109 having a plurality of first through holes is formed on the second sacrifice layer 108. In the present embodiment, the plurality of first through holes are formed in a flat region (first region) on a top face (ceiling) of the first cap film 109. One or more of through holes other than the plurality of first through holes may be formed in a region different from the first region of the first cap film 109. The plurality of first through holes are used to supply into the first cap film 109 gas for removing the first sacrifice layer 105 and the second sacrifice layer 108. The first cap film 111 is an inorganic film (for example, silicon oxide film) having a few hundred nm to a few μm thickness. The first cap film 109 is formed by, for example, CVD process.

The plurality of first through holes is obtained by, for example, forming a resist pattern (not shown) having a plurality of through holes on the inorganic thin film and processing the inorganic thin film by RIE method or wet etching method using the resist pattern as a mask.

The plurality of first through holes may be the same in size (for example, diameter or opening area) or, a size (S) (for example, diameter or opening area) of the first through hole communicating with a second through hole 113 (FIG. 10) to be described later, of the plurality of first through holes, may be different from a size (S′) of the remaining first through holes. For example, S<S′, or S<S′/2, and more specifically, S′ is 10 μm. The size S is not particularly limited if it is sufficient to suppress increase in pressure in the dome caused by rise in the substrate temperature. The pressure in the dome is, for example, equal to or lower than 10 kPa.

[FIG. 7]

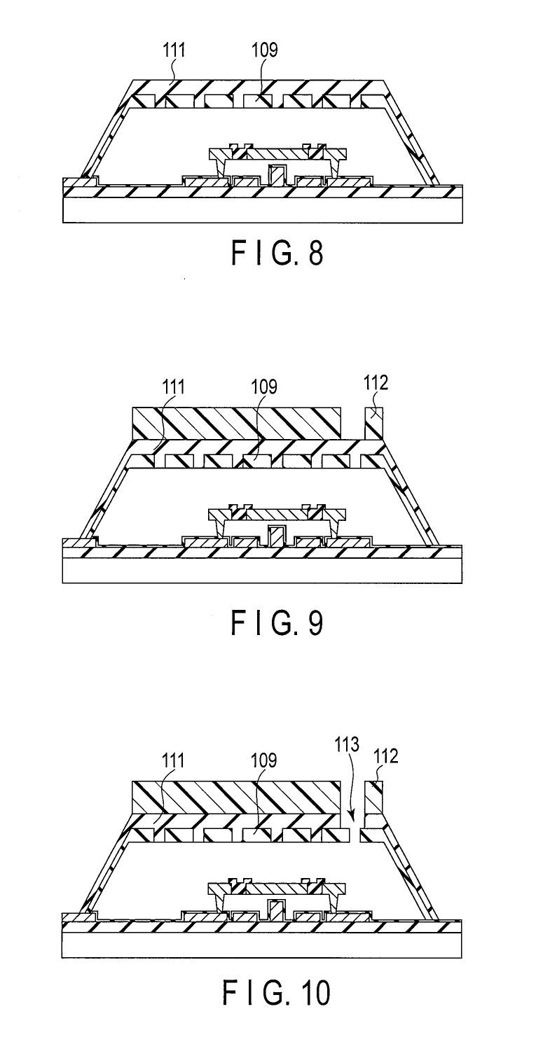

The resist pattern having the plurality of through holes, the first sacrifice layer 105 and the second sacrifice layer 108 are removed by asking using oxygen (O₂) gas or the like. Thereby, the MEMS element is released, and the cavity 110 that is an operational space for the MEMS element is formed by the substrate 100 and the first cap film 110.

[FIG. 8]

A second cap film 111 is formed on the first cap film 109 by coating method. In the present embodiment, the second cap film 112 is an organic film (insulating film) which uses organic substance such as polyimide based resin as a material. In this case, the second cap film 111 can be formed so as to fill the plurality of through holes of the first cap film 109, and a gas permeability of the second cap film 111 becomes higher than a gas permeability of the first cap film 109. The second cap film 112 is not needed to fill the plurality of first through holes as long as the second cap film 112 closes the plurality of first through holes.

[FIG. 9]

A resist pattern 112 having an opening portion is formed on the second cap film 111. The opening portion of the resist pattern 112 is positioned above a second through hole 113 (FIG. 10) to be described later.

In the present embodiment, a diameter of the opening portion of the resist pattern 112 is greater than a diameter of the first through holes. However, the diameter of the opening portion of the resist pattern 112 may be equal to or smaller than the diameter of the first through holes.

In the present embodiment, the only one opening portion of the resist pattern 112 is formed, but the number of the opening portions may be two or more if it is smaller than the number of the first through holes. Two or more opening portions of the resist pattern 112 are positioned on two or more first through holes, respectively.

[FIG. 10]

The second cap film 111 is etched by using the resist pattern 112 as a mask, and the second cap film 111 filling the through holes of the first cap film 109 is removed. As a result, a second through hole 113 is formed in the second cap film 111. The second through hole 113 communicates with the first through holes of the first cap film 109 positioned under the second through hole 113. That is, the second cap film 113 is formed to fill the plurality of first through holes, except the first through hole communicating with the second through hole 113. The second cap film 113 has the second through hole 113 communicating with one or some of the plurality of first through holes.

In the present embodiment, since the diameter of the opening portion of the resist pattern 112 is greater than the diameter of the first through holes, the size (for example, diameter or opening area) of the second through hole 112 is greater than that of the first through holes.

In the present embodiment, the only one second through hole 113 of the second cap film 111 is formed, but the number of second through holes may be two or more if it is smaller than the number of the first through holes. In this case, two or more second through holes 113 of the second cap film 111 communicate with two or more first through holes of the first cap film 109, respectively.

In the present embodiment, the second through hole 113 and the first through hole positioned under the second through hole 113 are formed in a flat portion of a ceiling (top face) of the thin film dome constituted by the first cap film 109 and the second cap film 111.

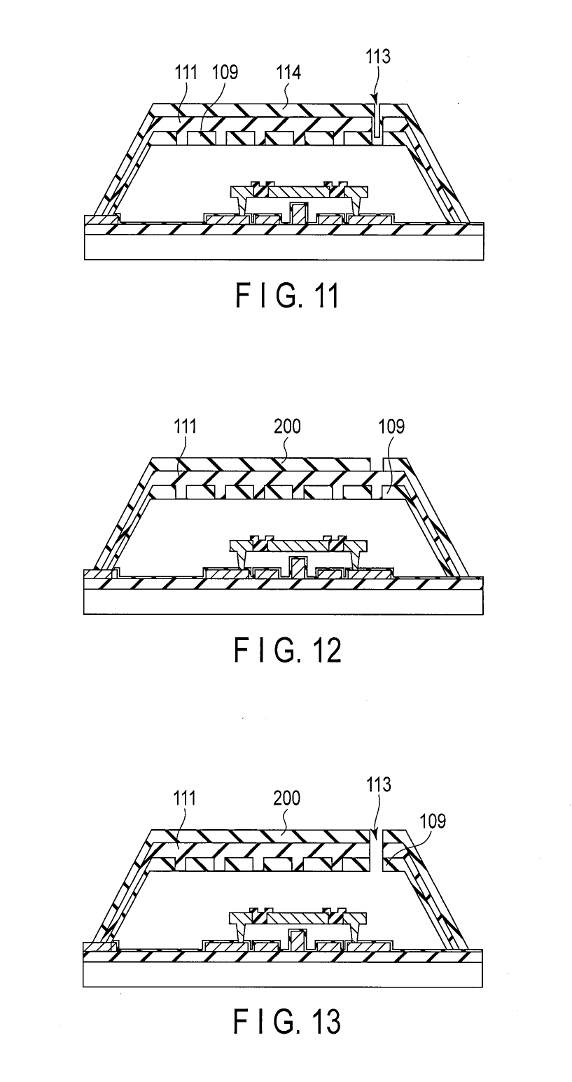

In the present embodiment, since the diameter of the opening portion of the resist pattern 112 is greater than the diameter of the first through holes of the first cap film 109, the second cap film 111 filling the through holes of the first cap film 109 are easily removed by etching. In addition, since the first cap film 109 is different in material from the second cap film 111, the second cap film 111 can be selectively etched.

[FIG. 11]

After the resist pattern 112 is removed, a third cap film 114 is formed on the second cap film 111 to close the first through hole under the second through hole 113, and a thin-film dome (cap films 109, 111, 114) of WLP is thereby completed. The third cap film 114 plays a role of a moisture-resistant film. For this purpose, the third cap film 114, preferably, should have a lower gas permeability than the second cap film 111. Such a relationship in gas permeability can be established by, for example, when the third cap film 114 is a deposition film by CVD method, and the second cap film 111 is a coating film by spin coating method.

A process for forming the third cap film 114 includes, for example, forming an insulation film such as a silicon nitride film with a few hundred nm to a few μm thickness by CVD method, forming a resist pattern on the insulation film by using photolithography method, and processing the insulation film by RIE method or wet etching method using the resist pattern as a mask.

Here, in a case of well-known MEMS device, when the pressure in the cavity is close to the atmospheric pressure, the pressure in the cavity increases according to the raising of temperature of the substrate. For this reason, the pressure in the cavity may be higher than the atmospheric pressure. Moreover, such a increasing of the pressure may cause an expansion of air in the cavity, and the diaphragm may be pushed up by the expansion of air.

In a case of the MEMS device of the present embodiment shown in FIG. 11, there exists the first through holes filled with the second cap film 111, and the first through hole (pressure adjusting portion) closed by the third cap film 114. For this reason, in the present embodiment, since the pressure in the cavity can be lowered by the pressure adjusting portion, the increasing of pressure in the cavity or the deformation of the diaphragm caused by variation in the substrate temperature can be suppressed.

In general, the increasing of the pressure in the cavity is suppressed as the number of pressure adjusting portions is increased. In general, the increasing of the pressure in the cavity is suppressed as the size (for example, diameter or opening area) of the pressure adjusting portion is greater.

FIG. 12 to FIG. 14 are cross-sectional views for explaining an alternative manufacturing method of the MEMS device according to the present embodiment. In this manufacturing method, the second through hole 113 is formed by using a hard mask 200 instead of the resist pattern 112.

First, steps in FIG. 1 to FIG. 8 are performed.

[FIG. 12]

The hard mask 200 is formed on the second cap film 111. The hard mask 200 is constituted of, for example, an insulating substance such as a silicon oxide. An opening portion of the hard mask 200 is positioned above the through hole of the first cap film 109.

A diameter of the opening portion of the hard mask 200 may be greater than the diameter of the through hole of the first cap film 109. In the present embodiment, the only one opening portion of the hard mask 200 is formed but the number of opening portions may be two or more. Two or more opening portions of the hard mask 200 are positioned above two or more through holes of the first cap film 109, respectively.

[FIG. 13]

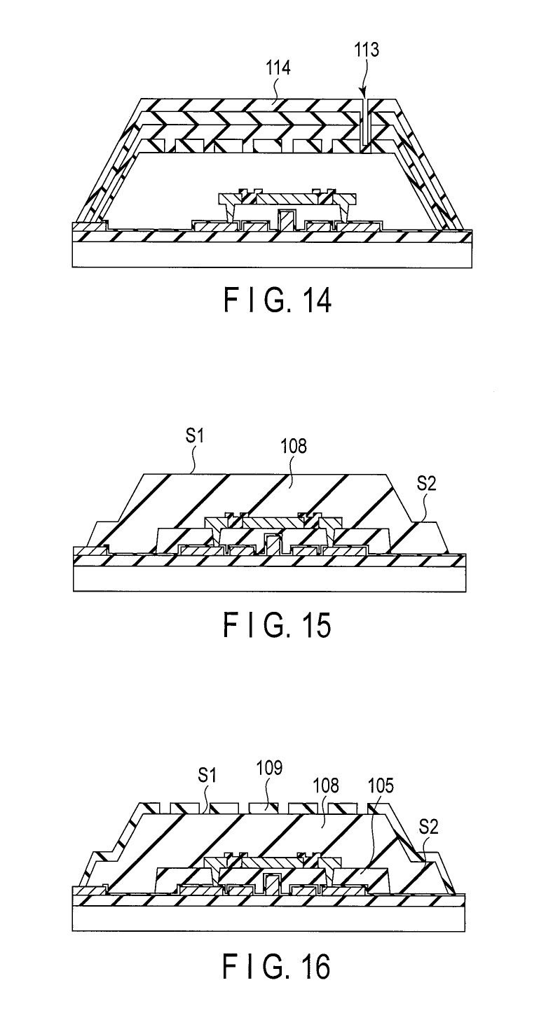

The second cap film 111 is etched by using the hard mask 200 as a mask, and the second cap film 111 filling the through hole of the first cap film 109 is removed. As a result, the second through hole 113 is formed in the second cap film 111. The second through hole 113 communicates with the first through hole of the first cap film 109 under the second through hole 113.

[FIG. 14]

The third cap film 114 is formed on the hard mask 200 to close the first through hole under the second through hole 113, thereby the thin-film dome (cap films 109, 111, 114) of WLP is completed.

### Second Embodiment

FIG. 15 to FIG. 19 are cross-sectional views for explaining a manufacturing method of a MEMS device according to second embodiment.

In the first embodiment, the first through hole of the first cap film 109, which supplies oxygen gas for removing the sacrifice layer, is utilized as a portion (the through hole closed by the third cap film 114) where the atmosphere hardly passes through. In the present embodiment, through holes (first through hole and second through hole), which penetrate through the first and second cap films 109, 111, and which are different from the first through hole of the sacrifice layer, are utilized as a portion (the through holes closed by the third cap film 114) where the atmosphere hardly passes through. A more detailed explanation is given below.

In the first embodiment, the plurality of first through holes of the first cap film 109 are utilized for the through holes through which oxygen gas is supplied to remove the sacrifice layers 105 and 108 (FIG. 7). And in the first embodiment, one of the plurality of first through holes used to supply the oxygen gas, and the second through hole formed in the second cap film 111 on the first through holes (first and second through holes communicating with each other) are used as a pressure adjusting portion.

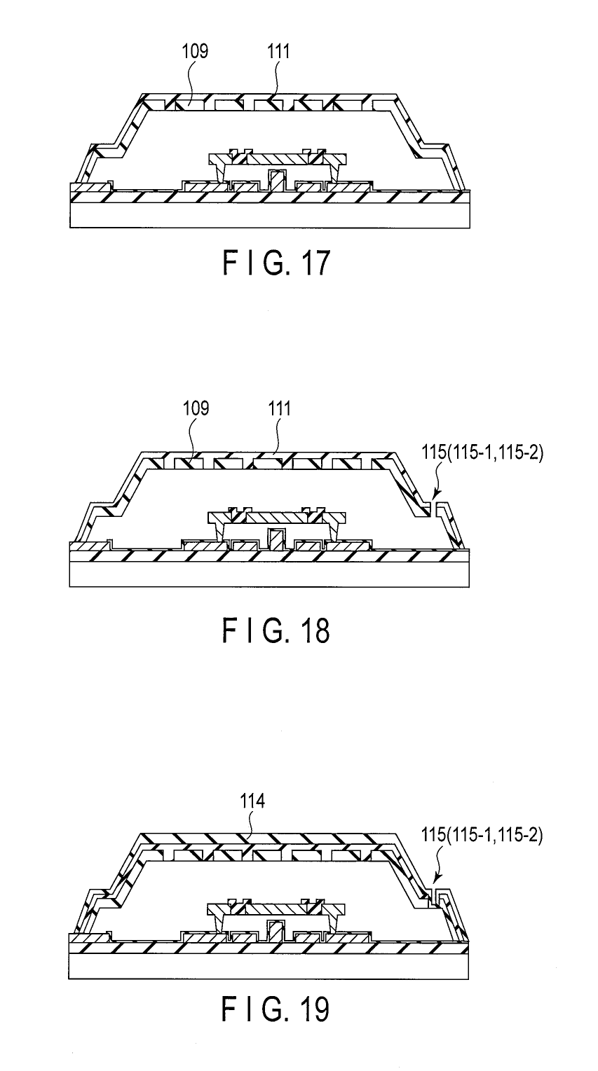

As mentioned later (FIG. 17), the first through holes of the first cap film 109 is utilized to supply oxygen gas for removing the sacrifice layer 105, 108 in the present embodiment, too. In the present embodiment, after removing sacrifice layers 105 and 108, through holes 115 (115-1 and 115-2) are formed in a laminated film of a first cap film 109 and a second cap film 111 (FIG. 21), and the through holes 115 (115-1 and 115-2) formed in a laminated film are used as a pressure adjusting portion. Among the through holes formed in the laminated film, the first through hole 115-1 formed in the first cap film 109 is different from the plurality of first through holes used to supply the oxygen gas. The different first through hole is not used for supply of the oxygen gas.

A MEMS device of the present embodiment comprising such a configuration is manufactured, for example, in the following manner.

First, steps in FIG. 1 to FIG. 4 are performed.

[FIG. 15]

A second sacrifice layer 108 having a predetermined shape covering a region including a movable portion of the MEMS element is formed. The second sacrifice layer 108 has flat top faces S1 and S2. The top face S2 is outside the top face S1 and is lower than the top face S1.

[FIG. 16]

The first cap film 109 having the plurality of first through holes is formed on the second sacrifice layer 108 by using photolithography method and etching method. The first cap film 109 includes a first region and a second region located outside the first region. In the present embodiment, the first region of the first cap film 109 is a region on the top face S1, and the second region of the first cap film 109 is a region on the top face S2. The second region may further include a region on a tapered side surface of the second sacrifice layer 108.

[FIG. 17]

The first sacrifice layer 105 and the second sacrifice layer 108 are removed by ashing using oxygen (O₂) gas or the like, thereafter, a second cap film 111 is formed on the first cap film 109. The plurality of first through holes of the first cap film 109 are closed by the second cap film 111. When the second cap film 111 is an organic film using organic substance such as polyimide base resin as a material, as shown in FIG. 17, the plurality of first through holes of the first cap film 109 are filled with the second cap film 111.

[FIG. 18]

A resist pattern (not shown) having an opening portion is formed on the second cap film 111, the second cap film 111 is etched by using the resist pattern as a mask, and the through holes 115 (115-1, 115-2) are formed in the laminated film of the first cap film 109 and the second cap film 111.

A portion of the through holes 115 which penetrates the first cap film 109 is hereinafter referred to as a first through hole 115-1. The first through hole 115-1 is a first through hole different from the plurality of first through holes formed in the step of FIG. 16. In addition, a portion of the through holes 115 communicating with the first through hole 115-1 and penetrating the second cap film 111 is referred to as a second through hole 115-2. A size (for example, diameter or opening area) of the first through hole 115-1 may be the same as or different from a size of the second through hole 115-2.

The first through hole 115-1 is formed in the flat first region of the first cap film 109, on the flat top face S2 of the sacrifice layer 108 shown in FIG. 16. The second through hole 115-2 is formed in the flat region of the second cap film on the first region. Since the region where the through holes 115 (115-1, 115-2) are formed is thus a flat region, the through holes 115 can be easily formed.

As the plurality of first through holes obtained after manufacturing the MEMS device are concerned, the plurality of first through holes, other than the first through hole 115-1 communicating with the second through hole 115-2, are provided in the first region of the first cap film 109 while the first through hole 115-1 communicating with the second through hole 115-2 is provided in the second region of the first cap film.

A size (S) of the first through holes 115 may be different from a size (S′) of the first through holes formed in the step of FIG. 16. For example, S<S′, or S<S′/2, more specifically, S′ is 10 μm. The size S is not particularly limited if it is sufficient to suppress increase in pressure in a dome caused by rise in a substrate temperature. The pressure in the dome is, for example, equal to or lower than 10 kPa.

[FIG. 19]

After the resist pattern is removed, a third cap film 114 is formed on the second cap film 111 to close the through holes 115 (115-1 and 115-2), thereby, the thin-film dome (the first to third cap films 109, 111, 114) of WLP is completed.

In the present embodiment, too, the same advantage as that of the first embodiment can be obtained.

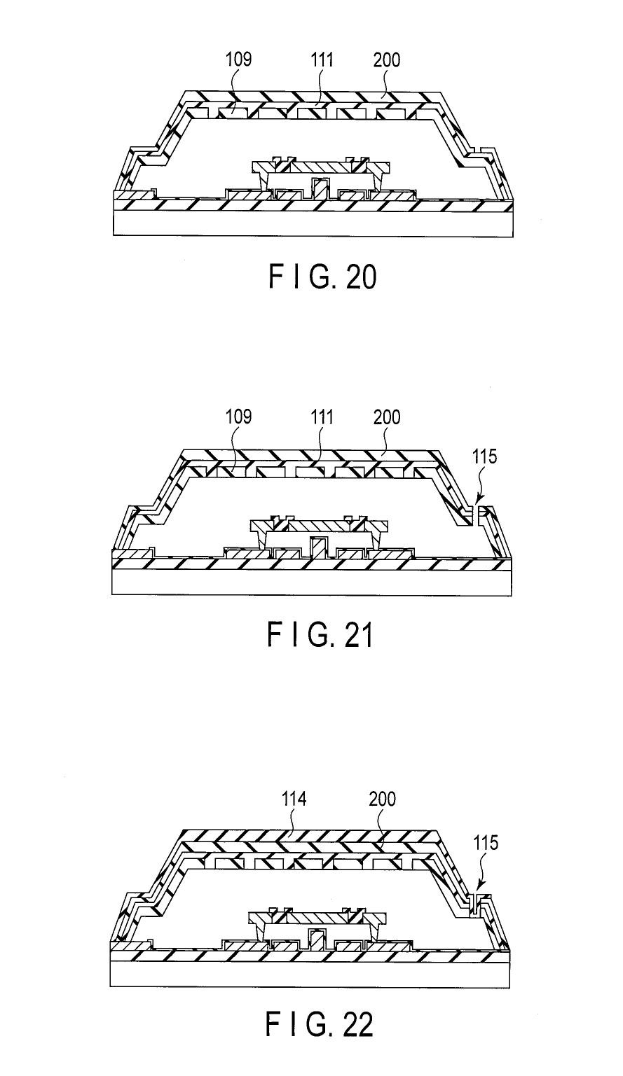

FIG. 20 to FIG. 22 are cross-sectional views for explaining an alternative manufacturing method of a MEMS device according to the second embodiment. In the manufacturing method, a second through hole 113 is formed by using a hard mask 200 instead of the resist pattern.

That is, the hard mask 200 is formed on the second cap film 111 as shown in FIG. 20, and the first cap film 109 and the second cap film 111 are etched by using the hard mask 200 as a mask to form a through hole 115 as shown in FIG. 21. After this, the third cap film 114 is formed on the hard mask 200 to close the through hole 115 as shown in FIG. 22.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a substrate;
a MEMS element provided on the substrate;
a first film comprising a plurality of first through holes, the first film and the substrate forming a cavity containing the MEMS element;
a second film provided on the first film, and comprising a second through hole communicating with a first through hole of the plurality of first through holes; and
a third film provided on the second film, and closing the first through hole communicating with the second through hole.

2. The device of claim 1, wherein the first film comprises a first region and a second region outside the first region, and wherein the plurality of first through holes are provided in the first region.

3. The device of claim 1, wherein the second film closes the plurality of first through holes except the first through hole communicating with the second through hole.

4. The device of claim 1, wherein the second film includes an organic film, and the second film fills the first through hole.

5. The device of claim 2, wherein the plurality of first through holes are same in size as each other.

6. The device of claim 2, wherein a size of the second through hole is greater than a size of the first through hole communicating with the second through hole.

7. The device of claim 1, wherein the first film comprises a first region and a second region outside the first region,
wherein the plurality of first through holes are provided in the first region of the first film except the first through hole communicating with the second through hole, and
wherein the first through hole communicating with the second through hole is provided in the second region of the first film.

8. The device of claim 7, wherein a size of the first through holes provided in the first region is different from a size of the first through hole provided in the second region.

9. The device of claim 1, further comprising a hard mask provided between the second film and the third film, and wherein the hard mask comprises an opening portion communicating with the second through hole.

10. The device of claim 1, wherein each of the first film, the second film and the third film is an insulating film.

11. The device of claim 1, wherein a gas permeability of the second film is higher than a gas permeability of the first film.

12. The device of claim 1, wherein a gas permeability of the third film is lower than a gas permeability of the second film.

13. A manufacturing method of a MEMS device comprising:
forming a MEMS element on a substrate;
forming a sacrifice layer covering the MEMS element on the substrate;
forming a first film comprising a plurality of first through holes on the sacrifice layer;
removing the sacrifice layer via the plurality of first through holes to form a cavity which contains the MEMS element, and comprises the substrate and the first film;
forming a second film on the first film to close the plurality of first through holes;
forming a second through hole in the second film, wherein the second through hole communicates with a first through hole of the plurality of first through holes; and
forming a third film on the second film to close the first through hole communicating with the second through hole.

14. The method of claim 13, wherein the first film comprises a first region and a second region outside the first region, and the plurality of first through holes are formed in the first region.

15. The method of claim 14, wherein the forming the second through hole comprises
forming a resist pattern on the second film, and
etching the second film using the resist pattern as a mask, and
wherein the third film is formed on the second film after removing the resist pattern.

16. The method of claim 13, wherein the first film comprises a first region and a second region outside the first region,
wherein the plurality of first through holes are provided in the first region of the first film except the first through hole communicating with the second through hole, and
wherein the first through hole communicating with the second through hole is provided in the second region of the first film.

17. The method of claim 16, wherein the forming the second through hole comprises
forming a hard mask on the second film, and
etching the second film and the first film using the hard mask as a mask, and
wherein the forming the third film comprises forming the third film on the second film via the hard mask.

18. The method of claim 13, wherein the sacrifice layer comprises an organic material.

19. The method of claim 13, wherein the removing the sacrifice layer comprises supplying gas containing oxygen to the sacrifice layer via the first through hole.

20. The method of claim 13, wherein the second film includes an organic film and the second film is formed to fill the plurality of first through holes.
